(19) United States
(12) Patent Application Publication
(10) Pub. No.: US 2018/0277340 A1
(43) Pub. Date: Sep. 27, 2018

(54) PLASMA REACTOR WITH ELECTRON BEAM OF SECONDARY ELECTRONS

(71) Applicants: Yang Yang, Los Gatos, CA (US); Kartik Ramaswamy, San Jose, CA (US); Kenneth S. Collins, San Jose, CA (US); Steven Lane, Porterville, CA (US); Gonzalo Antonio Monroy, San Francisco, CA (US); Lucy Chen, Santa Clara, CA (US); Yue Guo, Menlo Park, CA (US); Eswaranand Venkatasubramanian, Sunnyvale (CN)

(72) Inventors: Yang Yang, Los Gatos, CA (US); Kartik Ramaswamy, San Jose, CA (US); Kenneth S. Collins, San Jose, CA (US); Steven Lane, Porterville, CA (US); Gonzalo Antonio Monroy, San Francisco, CA (US); Lucy Chen, Santa Clara, CA (US); Yue Guo, Menlo Park, CA (US); Eswaranand Venkatasubramanian, Sunnyvale (CN)

(21) Appl. No.: 15/948,949

(22) Filed: Apr. 9, 2018

Related U.S. Application Data
(63) Continuation-in-part of application No. 15/717,822, filed on Sep. 27, 2017.
Application No. 15/717,822 is a continuation of application No. PCT/US2018/022453, filed on Mar. 14, 2018.
Application No. PCT/US2018/022453 is a continuation-in-part of application No. 15/717,897, filed on Sep. 27, 2017.
Application No. 15/717,897 is a continuation-in-part of application No. 15/717,822, filed on Sep. 27, 2017.
(60) Provisional application No. 62/476,186, filed on Mar. 24, 2017.
(60) Provisional application No. 62/476,186, filed on Mar. 24, 2017.

(51) Int. Cl. H01J 37/32; H01L 21/02

(52) U.S. Cl. CPC H01J 37/32568; H01L 21/02115; H01L 21/0234; H01J 37/32669; H01J 2237/334; H01J 37/32715; H01J 37/3244; H01J 2237/332; H01J 37/32183

(57) ABSTRACT

An electron beam plasma reactor includes a plasma chamber having a side wall, an upper electrode, a workpiece support to hold a workpiece facing the upper electrode with the workpiece on the support having a clear view of the upper electrode, a first RF power source coupled to said upper electrode, a gas supply, a vacuum pump coupled to the chamber to evacuate the chamber, and a controller. The controller is configured to operate the first RF power source to apply an RF power to upper electrode, and to operate the gas distributor and vacuum pump, so as to create a plasma in an upper portion of the chamber that generates an electron beam from the upper electrode toward the workpiece and a lower electron-temperature plasma in a lower portion of the chamber including the workpiece.

### CROSS-REFERENCE TO RELATED APPLICATIONS

This application is a continuation of PCT Application Serial No. PCT/US2018/022453, filed on Mar. 14, 2018, which claims priority to U.S. application Ser. No. 15/717,897, filed Sep. 27, 2017 and to U.S. application Ser. No. 15/717,822, filed Sep. 27, 2017, each of which claims priority to U.S. Provisional Application Ser. No. 62/476,186, filed Mar. 24, 2017. This application is also a continuation-in-part of U.S. application Ser. No. 15/717,822, filed Sep. 27, 2017.

### BACKGROUND

### Technical Field

The disclosure concerns a plasma reactor, and deposition or treatment in a plasma reactor of diamond-like carbon on a workpiece such as a semiconductor wafer.

### Background Discussion

Some plasma sources for processing a workpiece include an electron beam source having a beam path that passes through a region of the processing chamber that is separated from the substrate by a grid filter.

Diamond-like carbon (DLC) has been used as a coating in various applications such as industrial tools, medical instruments, and the like. Carbon layers with some portion of diamond-like carbon have been used as an etchant mask for some semiconductor fabrication processes. Diamond-like carbon has been deposited by plasma.

### SUMMARY

In one aspect, a method of performing deposition of diamond-like carbon on a workpiece in a chamber includes supporting the workpiece in the chamber facing an upper electrode suspended from a ceiling of the chamber, introducing a hydrocarbon gas into the chamber, and applying first RF power at a first frequency to the upper electrode that generates a plasma in the chamber and produces a deposition of diamond-like carbon on the workpiece. Applying the RF power generates an electron beam from the upper electrode toward the workpiece to enhance ionization of the hydrocarbon gas.

Implementations may include one or more of the following features.

The first frequency may be between 100 kHz and 27 MHz. The first frequency may be less than 12 MHz, e.g., the first frequency may be about 2 Mhz. Second RF power may be applied at a second frequency to a lower electrode in a pedestal that supports the workpiece while the first RF power is applied to the upper electrode. The first frequency may be equal to or less than the second frequency.

An inert gas may be introduced into the chamber such the plasma is a plasma of both the hydrocarbon gas and the inert gas.

After deposition of a layer of diamond-like carbon on the workpiece, the hydrocarbon gas may be removed from the chamber. After removing the hydrocarbon gas, an inert gas may be introduced into the chamber, and third RF power may be applied at a third frequency to the upper electrode that generates a plasma of the inert gas in the chamber and generates an electron beam from the upper electrode toward the workpiece, the electron beam impinging the layer of diamond-like carbon. Impinging the layer of diamond-like carbon with the electron beam may reduce internal stress in the layer. Fourth RF power may be applied at a fourth frequency to a lower electrode in a pedestal that supports the workpiece while the third RF power is applied to the upper electrode.

In another aspect, a method of treating a layer of diamond-like carbon on a workpiece includes supporting the workpiece in a chamber with the layer of diamond-like carbon facing an upper electrode, introducing an inert gas into the chamber, and applying first RF power at a first frequency to the upper electrode that generates a plasma in the chamber and generates an electron beam from the upper electrode toward the workpiece, the electron beam impinging the layer of diamond-like carbon.

Implementations may include one or more of the following features.

Impinging the layer of diamond-like carbon with the electron beam may reduce internal stress in the layer. Second RF power may be applied at a second frequency to a lower electrode in a pedestal that supports the workpiece. The first frequency may be equal to or less than the second frequency. The inert gas may include argon or helium.

In another aspect, a method of treating a layer of diamond-like carbon on a workpiece, includes supporting the workpiece in a chamber with the layer of diamond-like carbon facing an upper electrode, introducing an inert gas into the chamber, and applying first RF power at a first frequency to the upper electrode such that a plasma of the inert gas is generated in the chamber and the layer of diamond-like carbon is exposed to the plasma of the inert gas.

Implementations may include one or more of the following features.

The inert gas may include argon or helium. Second RF power may be applied at a second frequency to a lower electrode in a pedestal that supports the workpiece.

In another aspect, an electron beam plasma reactor includes a plasma chamber having a side wall, an upper electrode, a first RF source power generator coupled to the upper electrode, a gas supply to provide a hydrocarbon gas, a gas distributor to deliver the hydrocarbon gas to the chamber, a vacuum pump coupled to the chamber to evacuate the chamber, a workpiece support pedestal to hold a workpiece facing the upper electrode, and a controller configured to operate the upper electrode, gas distributor and vacuum pump to generate a plasma in the chamber that produces a deposition of diamond-like carbon on the workpiece and cause the first RF source to apply an RF power that generates an electron beam from the upper electrode toward the workpiece to enhance ionization of the hydrocarbon gas.

In another aspect, an electron beam plasma reactor includes a plasma chamber having a side wall, an upper electrode, a first RF source power generator coupled to the upper electrode, a gas supply to provide an inert gas, a gas distributor to deliver the inert gas to the chamber, a vacuum pump coupled to the chamber to evacuate the chamber, a workpiece support pedestal to hold a workpiece facing the upper electrode, and a controller configured to operate the upper electrode, gas distributor and vacuum pump to generate a plasma in the chamber that anneals a layer of diamond-like carbon on the workpiece and to cause the first RF source to apply an RF power that generates an electron beam from the upper electrode toward the workpiece to impinge the layer of diamond-like carbon.

In another aspect, an electron beam plasma reactor includes a plasma chamber having a side wall, an upper electrode, a first RF source power generator coupled to said upper electrode, a first gas supply to provide a hydrocarbon gas, a second gas supply to provide an inert gas, a gas distributor to deliver the hydrocarbon gas and the inert gas to the chamber, a vacuum pump coupled to the chamber to evacuate the chamber, a workpiece support pedestal to hold a workpiece facing the upper electrode, and a controller configured to operate the upper electrode, gas distributor and vacuum pump to alternate between depositing a layer of diamond-like carbon on the workpiece and treating the workpiece with an electron beam from the upper electrode.

Implementations may include one or more of the following features.

The controller may be configured to cause the gas distributor to deliver the hydrocarbon gas from the first gas supply into the chamber, and cause the first RF power source to apply first RF power at a first frequency to the upper electrode to generate a plasma in the chamber and produce deposition of the layer of diamond-like carbon on the workpiece. A lower electrode and a second RF source power generator may be coupled to the lower electrode and configured to apply second RF power at a second frequency to the upper electrode. The controller may be configured to cause the vacuum pump to remove the hydrocarbon gas from the chamber after deposition of the layer of diamond-like carbon on the workpiece. The controller may be configured to cause the gas distributor to deliver the inert gas from the second gas supply into the chamber after the hydrocarbon gas is removed, and cause the first RF power source to apply third RF power at a third frequency to the upper electrode to generate a plasma of the inert gas in the chamber and generate an electron beam from the upper electrode toward the workpiece, the electron beam impinging the layer of diamond-like carbon to treat the workpiece.

In another aspect, a method of forming a layer of diamond-like carbon on a workpiece includes supporting the workpiece in a chamber with the workpiece facing an upper electrode, and forming a plurality of successive sublayers to form the layer of diamond-like carbon by alternating between depositing a sublayer of diamond-like carbon on the workpiece in the chamber and treating the sublayer with a plasma of the inert gas or an electron beam from the upper electrode.

Implementations may include one or more of the following features.

Depositing a sublayer of diamond-like carbon on the workpiece comprises introducing a hydrocarbon gas into the chamber and applying first RF power at a first frequency to the upper electrode that generates a plasma in the chamber and produces a deposition of the sublayer of diamond-like carbon on the workpiece. Applying the first RF power may generate an electron beam from the upper electrode toward the workpiece to enhance ionization of the hydrocarbon gas.

Treating the sublayer may include introducing an inert gas into the chamber and applying first RF power at a second frequency to the upper electrode that generates a plasma of the inert gas in the chamber. Applying the second RF power may generate an electron beam from the upper electrode that impinges the sublayer of diamond-like carbon on the workpiece.

In another aspect, a method of treating or depositing a layer of diamond-like carbon on a workpiece in a chamber includes supporting the workpiece on a pedestal in the chamber, the workpiece facing an upper electrode suspended from a ceiling of the chamber, introducing an inert gas and/or hydrocarbon gas into the chamber, applying first RF power at a first frequency to the upper electrode that generates a plasma of an inert gas and/or hydrocarbon gas in the chamber to anneal a layer of diamond-like carbon on the substrate or produce a deposition of diamond-like carbon on the workpiece, and applying second RF power at a plurality of discrete frequencies simultaneously to a lower electrode in the pedestal, the plurality of frequencies including second frequency and a third frequency that is higher than the second frequency.

Implementations may include one or more of the following features.

The first frequency may be less than the third frequency. The first frequency may be equal to or less than the second frequency. The second frequency may be less than 2 MHz. The third frequency may be greater than 2 MHz.

In another aspect, an electron beam plasma reactor includes a plasma chamber having a side wall, an upper electrode, a first RF source power generator coupled to said upper electrode, the first RF source power generator configured to apply first RF power at a first frequency to the upper electrode, a first gas supply to provide a hydrocarbon gas, a second gas supply to provide an inert gas, a gas distributor to deliver the hydrocarbon gas and the inert gas to the chamber, a vacuum pump coupled to the chamber to evacuate the chamber, a workpiece support pedestal to hold a workpiece facing the upper electrode, a lower electrode, a second RF source power generator coupled to the lower electrode, the second RF source power generator configured to apply second RF power at a plurality of frequencies simultaneously to the lower electrode, the plurality of frequencies including second frequency and a third frequency that is higher than the second frequency, and a controller configured to operate the upper electrode, lower electrode, gas distributor and vacuum pump to deposit or anneal a layer of diamond-like carbon on the workpiece.

Implementations may include one or more of the following features.

The lower electrode may be supported by the workpiece support pedestal.

The first frequency may be less than the third frequency. The first frequency may be equal to or less than the second frequency. The second frequency may be less than 2 MHz. The third frequency may be greater than 2 MHz.

Implementation may include, but are not limited to, one or more of the following advantages. An electron beam may be applied to a substrate without an intervening grid filter, providing increased electron density. The deposition can be increased, e.g., to greater than 6 μm/hour at intermediate power levels. The electron beam may enhance ionization of the hydrocarbon gases and increase the hydrocarbon density. The proportion of high energy electrons can be increased, and the ratio of ions to neutrals can be increased. This can increase the film density, e.g., to about 2 g/cm³. In addition, the electron beam can “cure” the deposited diamond-like carbon film to reduce film stress. For example, the film stress can be less than 500 MPa. The support pedestal for the workpiece does not need to be heated.

The details of one or more implementations are set forth in the accompanying drawings and the description below. Other potential features, aspects, and advantages will become apparent from the description, the drawings, and the claims.

### BRIEF DESCRIPTION OF THE DRAWINGS

FIG. 1 depicts a plasma reactor.

FIG. 2 depicts another implementation of a plasma reactor in accordance with a second embodiment.

FIG. 3 is a block diagram flow chart depicting a method of depositing a film of diamond-like carbon.

FIG. 4 is a block diagram flow chart depicting a method of treating a film of diamond-like carbon.

Like reference numbers and designations in the various drawings indicate like elements.

### DETAILED DESCRIPTION

### Introduction

For some processes, it is desirable to expose a workpiece to an electron beam while the workpiece is in the presence of a low-energy plasma. In general, generation of such an electron beam is accompanied by a high-energy plasma. One technique is to interpose a grid filter between an upper chamber and a lower chamber; secondary electrons generated from an electrode in the upper chamber can propagate through the grid filter into the lower chamber, where a low-energy plasma is generated and the workpiece is held. The grid filter prevents the high energy plasma from reaching the workpiece, and also ensures that electrons having a desired propagation direction (generally perpendicular to the workpiece surface) pass into the lower chamber. However, the grid filter also limits the density of the electron beam.

However, it is possible to generate an electron beam in a chamber that lacks such a grid filter. By establishing appropriate reactor configuration, e.g., distance between the electrode and the workpiece, energy of the plasma can be high near the electrode in order to generate the secondary electrons that provide the electron beam, but low near the workpiece.

In addition, it is desirable to increase the density of a film of diamond-like carbon deposited on a workpiece, e.g., a semiconductor wafer being used for fabrication of integrated circuits. For example, an increased film density can provide superior performance as an etch stop layer. Increased film density can also reduce critical dimension variation across the workpiece. Unfortunately, increasing the film density can cause the film stress to increase, which can cause the diamond-like carbon film to peel off the workpiece or cause the workpiece to bow. For example, a diamond-like carbon film having a density greater than 2 g/cm³, at about 1 μm thickness of the film, a stress less than 500 MPa and workpiece bowing less than 200 μm, could provide superior characteristics.

Two techniques can be used to improve fabrication of a film of diamond-like carbon. First, during deposition, a high energy electron beam can be used to enhance ionization of hydrocarbon gas; these hydrocarbon ions are implanted into the growing film to increase the film density. Second, during or after deposition, the film of diamond-like carbon can be exposed to the high energy electron beam; this “cures” (or anneals) the diamond-like carbon film and reduces the film stress. Without being limited to any particular theory, this curing or annealing can change the bonding structure of the carbon film, e.g., decrease dangling bonds and increase cross-linking.

### System

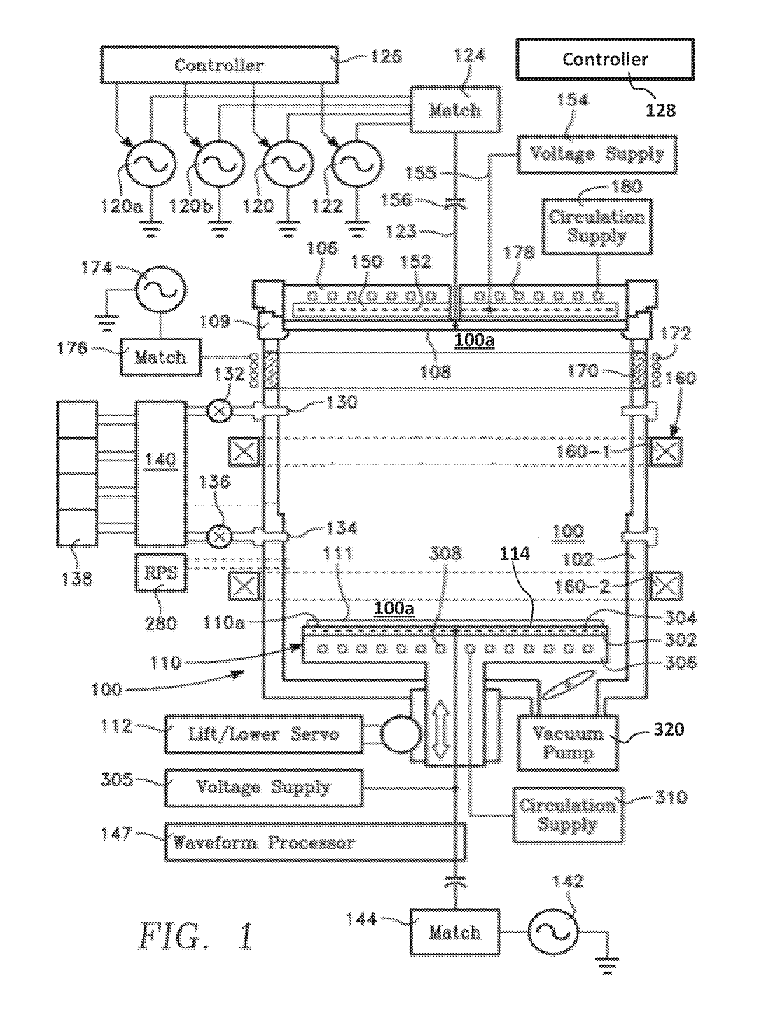

Referring to FIG. 1, an electron beam plasma reactor has a vacuum chamber body defining a chamber 100 including a side wall 102 of cylindrical shape. A ceiling 106 overlies the chamber 100, and supports an upper electrode 108. The upper electrode 108 can be formed of a process-compatible material such as silicon, carbon, silicon carbon compound or a silicon-oxide compound, or of a metal oxide such as aluminum oxide, yttrium oxide, or zirconium oxide. The ceiling 106 and the upper electrode 108 may be disk-shaped. In some implementations, an insulator or dielectric ring 109 surrounds the upper electrode 108.

A workpiece support pedestal 110 for supporting a workpiece 111 is positioned in the chamber 100. The pedestal 110 has a workpiece support surface 110a facing the upper electrode 108 and can be movable in the axial direction by a lift servo 112. In some implementations, the workpiece support pedestal 110 includes an insulating puck 302 forming the workpiece support surface 110a, a workpiece electrode 304 inside the insulating puck 302, and a chucking voltage supply 305 connected to the workpiece electrode 304. Additionally, a base layer 306 underlying the insulating puck 302 has internal passages 308 for circulating a thermal medium (e.g., a liquid) from a circulation supply 310. The circulation supply 310 may function as a heat sink or as a heat source.

An RF power generator 120 having a VHF frequency (e.g., 160 MHz) and a lower frequency RF power generator 122 having a frequency below the VHF range or below the HF range (e.g., in the MF or LF range, e.g., 2 MHz) are coupled to the upper electrode 108 through an impedance match 124 via an RF feed conductor 123. The impedance match 124 can be adapted to provide an impedance match at the different frequencies of the RF power generators 120 and 122, as well as filtering to isolate the power generators from one another. The output power levels of the RF generators 120, 122 are independently controlled by a controller 126. As will be described in detail below, power from the RF power generators 120, 122 is coupled to the upper electrode 108.

In some implementations, the ceiling 106 can be electrically conductive and in electrical contact with the upper electrode 108, and the power from the impedance match 124 can be conducted through the ceiling 106 to the upper electrode 108. The side wall 102 can be formed of metal and is grounded. The surface area of grounded internal surfaces inside the chamber 100 can be at least twice the surface area of the upper electrode 108. The grounded internal surfaces inside the chamber 100 can be coated with a process compatible material such as silicon, carbon, silicon carbon compound or a silicon-oxide compound, or with a material such as aluminum oxide, yttrium oxide, or zirconium oxide.

In some implementations, the ceiling 106 is a support for the upper electrode 108 and includes an insulating layer 150 containing a chucking electrode 152 facing the upper electrode 108. A D.C. chucking voltage supply 154 is coupled to the chucking electrode 152 via the feed conductor 155, for electrostatically clamping the upper electrode 108 to the ceiling 106. A D.C. blocking capacitor 156 may be connected in series with the output of the impedance match 124. The controller 126 may control the D.C. chucking voltage supply 154. The RF feed conductor 123 from the impedance match 124 can be connected to the electrode support or ceiling 106 rather than being directly connected to the upper electrode 108. In such an embodiment, RF power from the RF feed conductor 123 can be capacitively coupled from the electrode support to the upper electrode 108.

In one embodiment, gas injectors 130 provide one or more process gases into the chamber 100 through a valve 132 and/or valve 134. A vacuum pump 320 can be used to evacuate the chamber 100.

Plasma can be produced in the chamber 100 by various bulk and surface processes, including energetic ion bombardment of the interior surface of the electron-emitting upper electrode 108. The ion bombardment energy of the upper electrode 108 and the plasma density are functions of both RF power generators 120 and 122. The ion bombardment energy of the upper electrode 108 can be substantially controlled by the lower frequency power from the RF power generator 122 and the plasma density in the chamber 100 can be substantially controlled (enhanced) by the VHF power from the RF power generator 120. Energetic secondary electrons may be emitted from the interior surface of the upper electrode 108. The flux of energetic electrons from the emitting surface may comprise an electron beam, and may have a direction substantially perpendicular to the interior surface of the upper electrode 108, and a beam energy of approximately the ion bombardment energy of the upper electrode 108, which typically can range from about 10 eV to 5000 eV. The collision cross-sections for different processes depend upon the electron energy. At low energies, cross-sections for excitation (and dissociation in molecular gases) are larger than for ionization, while at high energies the reverse is true. The RF power level(s) may be advantageously selected to target various inelastic electron collision processes.

In some implementations, the plasma density in the chamber 100 can be substantially controlled (enhanced) by the RF power from an optional RF power generator 174 and coil antenna 172.

At least a portion of the electron beam, comprised of the secondary electron flux emitted from upper electrode 108 due to energetic ion bombardment of the electrode surface, propagates through chamber 100, producing a low electron temperature plasma, with a plasma density that depends upon beam energy and flux, as well as other factors such as pressure and gas composition. The electron beam has a beam propagation direction substantially perpendicular to both the surface of the upper electrode 108 and the surface of the workpiece. The energetic beam electrons can also impinge upon the workpiece 111 or workpiece support pedestal 110. The plasma left behind may readily discharge any resultant surface charge caused by the electron beam flux.

As shown in FIG. 1, there is no grid filter or similar barrier between the upper electrode 108 and the workpiece support surface 110a. However, the distance between the upper electrode 108 and the workpiece support surface 110a can establish a temperature gradient in the plasma vertically through the chamber 100. In particular, the distance (and other chamber configuration features such as location of the magnets and coil antenna) can be sufficiently large, e.g., about 5 cm or more, that the plasma is hot enough in the region near the upper electrode 108, e.g., in the upper portion 100a of the chamber 100, to generate the secondary electron flux from the upper electrode 108, but cool enough in the region near the workpiece 111, e.g., in the lower portion 100b, to be compatible with low-temperature plasma processes. In addition, the distance between the upper electrode 108 and the workpiece support surface 110a can be sufficiently large that the secondary electrons that reach the workpiece have a limited angular distribution and can still be considered a “beam.”

A substantially axially-directed magnetic field, substantially parallel to the electron beam, can be optionally used to help guide the electron beam, improving beam transport through the chamber 100. A low frequency bias voltage or arbitrary waveform of low repetition frequency may be applied to a lower electrode 114 that is on or in the workpiece support pedestal 110. The lower electrode 114 can be provided by the workpiece electrode 304, or can be a separate electrode in or on the pedestal 110. The low frequency bias voltage or waveform can selectively or alternately extract positive and/or negative ions from the plasma and accelerate those ions at desired energy levels to impact the surface of the workpiece 111 for etching, cleaning, deposition, or other materials modification.

In some implementations, an RF bias power generator 142 is coupled through an impedance match 144 to the workpiece electrode 304 of the workpiece support pedestal 110.

In some implementations, a magnet 160 surrounds the chamber 100. The magnet can comprise a pair of magnets 160-1, 160-2 adjacent to an upper chamber portion 100a and a lower chamber portion 100b of the chamber 100, respectively. The pair of magnets 160-1, 160-2 can provide an axial magnetic field suitable for confining an electron beam that is propagating from the upper chamber portion 100a to the lower chamber portion 100b.

In some implementations, a side window 170 in the side wall 102 to the chamber 100 is formed of a material (e.g., quartz or aluminum oxide) through which RF power may be inductively coupled. An inductive coil antenna 172 surrounds the side window 170 and is driven by an RF power generator 174 through an impedance match 176. As illustrated, the window 170 can be significantly closer to the upper electrode 108 than the workpiece support surface 110a, e.g., in the upper 25% of the chamber 100. The remote plasma source 280 may introduce plasma species into the lower chamber 100b.

In some implementations, internal passages 178 for conducting a thermally conductive liquid or media inside the ceiling 106 are connected to a thermal media circulation supply 180. The thermal media circulation supply 180 acts as a heat sink or a heat source. The mechanical contact between the upper electrode 108 and the ceiling 106 is sufficient to maintain high thermal conductance between the upper electrode 108 and the ceiling 106. In the embodiment of FIG. 1, the force of the mechanical contact is regulated by the electrostatic clamping force provided by the D.C. chucking voltage supply 154.

In an alternative embodiment, an RF-driven coil antenna 290 may be provided over the ceiling 106.

A master controller 128, e.g., general purpose programmable computer, is connected to and operable to control some or all of the various components of the plasma reactor, e.g., the RF power supplies 120, 122, 142, 154, 174, 350, the pumps and valves 132, 136, 140, 320, the actuators 112, and circulation supplies 180, 310.

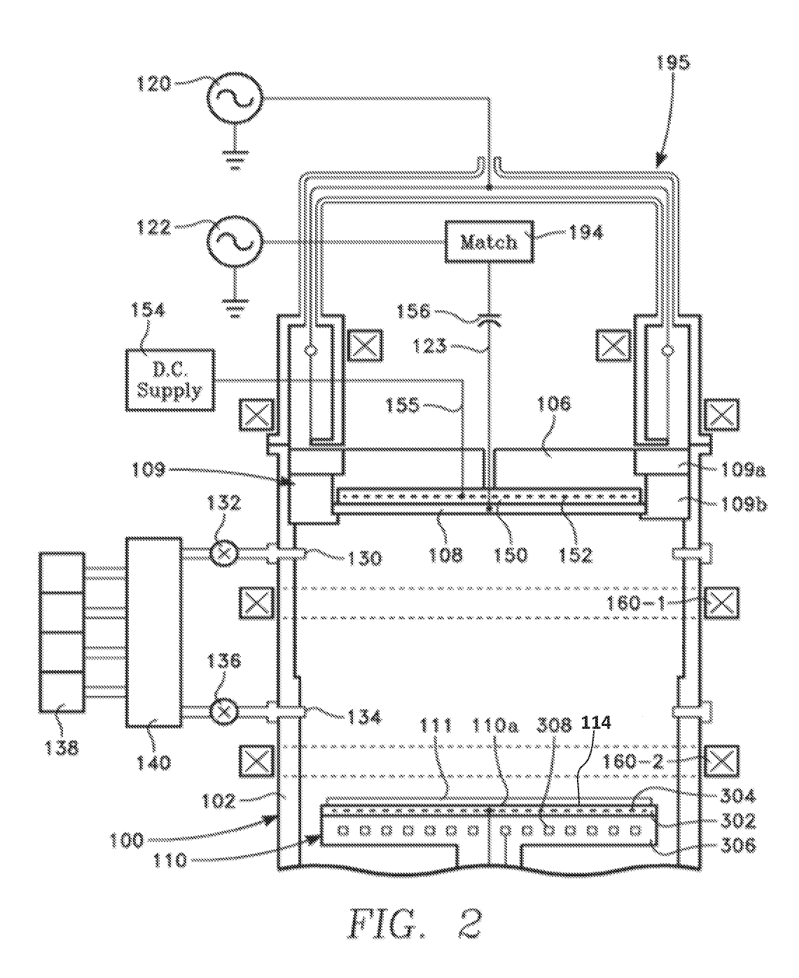

FIG. 2 depicts a modification of the embodiment of FIG. 1 in which the RF power (from the RF generator 120) and the lower frequency RF power (from the RF generator 122) are delivered to the upper electrode 108 through separate paths. In the embodiment of FIG. 2, the RF generator 120 is coupled to the upper electrode 108 through a folded resonator 195 overlying an edge of the upper electrode 108. The lower frequency RF generator 122 is coupled to the upper electrode 108 via the RF feed conductor 123 through an RF impedance match 194. The D.C. chucking voltage supply 154 is coupled to the chucking electrode 152 through the feed conductor 155 extending through a passage in the ceiling 106.

For some processes, a hydrocarbon gas is furnished into the chamber 100, and RF power is applied to the upper electrode 108, RF power is optionally applied to coil antenna 172 and RPS power is optionally applied to a remote plasma source (RPS) 280. Optionally an inert gas can be furnished into the chamber as well. A plasma is generated in the upper chamber 100 and an accelerating voltage is developed on the upper electrode 108 with respect to ground and with respect to the plasma. The resulting energetic ion bombardment of the upper electrode 108 produces secondary electron emission from electrode surface, which constitutes an electron beam flux from the electrode surface. This electron beam flux provides an electron beam which enhances ionization of hydrocarbon gas.

For some processes, an inert gas is furnished into the chamber 100, and RF power is applied to the upper electrode 108, RF power is optionally applied to coil antenna 172 and RPS power is optionally applied to a remote plasma source (RPS) 280. A plasma is generated in the upper chamber 100 and an accelerating voltage is developed on the upper electrode 108 with respect to ground and with respect to the plasma. The resulting energetic ion bombardment of the upper electrode 108 produces secondary electron emission from electrode surface, which constitutes an electron beam flux from the electrode surface. This electron beam flux provides an electron beam which impinges the surface of the workpiece.

Any one the electron beam plasma reactors described above may be employed to carry out the following method of processing a workpiece in an electron beam plasma reactor.

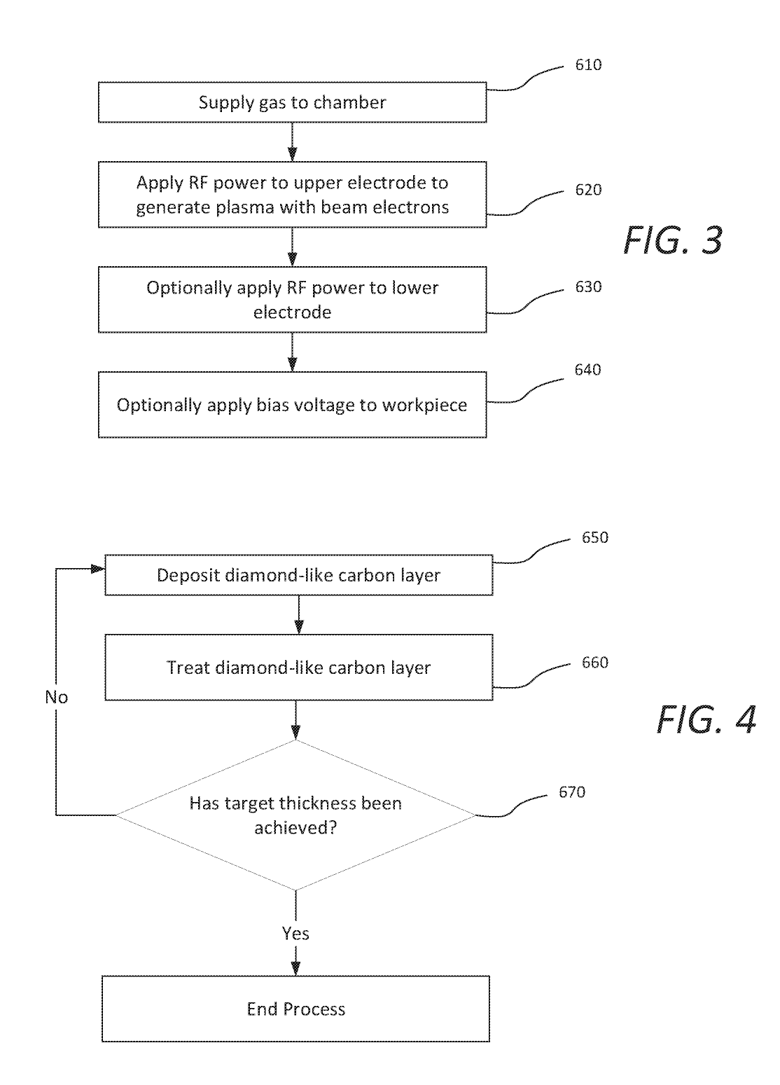

Referring now to FIG. 3, a gas is supplied to the chamber 100 (610). As discussed below, the gas can be a hydrocarbon gas and/or an inert gas, depending on the process, e.g., deposition or “curing.” RF power is applied to the upper electrode 108 to generate a plasma that includes beam electrons (620). The beam electrons provide an electron beam having a beam propagation direction substantially perpendicular to both the surface of the upper electrode 108 and the surface of the workpiece 111. The method can optionally include applying RF power to the lower electrode 114 (630). The method can further include applying coupling a bias voltage to the workpiece 111 (640).

Where the gas includes hydrocarbons, the RF power applied to the upper electrode 108 can ionize and dissociate the hydrocarbon gas. RF power applied to the lower electrode can accelerate hydrocarbon ions to implant into the film being grown, but can also ionize and dissociate the hydrocarbon gas. In addition, the beam electrons can also ionize and dissociate the hydrocarbon gas.

Where the gas is purely inert, the beam electrons can also ionize and dissociate the inert gas, and can pass through and impinge the workpiece.

The controllers, e.g., the controller 126 and/or 128, can be implemented in digital electronic circuitry, or in computer software, firmware, or hardware, or in combinations of them. The controller can include one or more computer program products, i.e., one or more computer programs tangibly embodied in an information carrier, e.g., in a non-transitory machine readable storage medium or in a propagated signal, for execution by, or to control the operation of, data processing apparatus, e.g., a programmable processor, a computer, or multiple processors or computers. A computer program (also known as a program, software, software application, or code) can be written in any form of programming language, including compiled or interpreted languages, and it can be deployed in any form, including as a standalone program or as a module, component, subroutine, or other unit suitable for use in a computing environment. A computer program can be deployed to be executed on one computer or on multiple computers at one site or distributed across multiple sites and interconnected by a communication network.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

For example, the controller 128 can be programmed to generate control signals that cause the components of the plasma reactor to carry out the process described below.

### Deposition or Treatment of Diamond-Like Carbon

The reactor of FIG. 1 or FIG. 2 may be employed to perform deposition or treatment of a film of diamond-like carbon. In one example, the workpiece 111 includes a semiconductive bulk layer (e.g., monocrystalline Silicon) onto which the film of diamond-like carbon is to be deposited.

In a process for deposition of the diamond-like carbon, a feedstock gas is supplied to the chamber 100 by the gas supply 138. The feedstock gas includes at least a hydrocarbon compound, e.g., C₂H₂, CH₂H₂, C₃H₆, norbornadinene, etc.

An inert gas, e.g., argon or helium, can also be supplied to the chamber 100. The inert gas can be used to dilute the feedstock gas; this can increase plasma density. The inert gas can be mixed with the feedstock gas before being delivered into the chamber 100, or the inert gas could be delivered by separate nozzles 130, 134, and mix in the chamber. In some implementations, the gas supply can establish a total pressure (feedstock and inert gas) of 2 to 100 mTorr.

RF power at a first frequency is applied to the upper electrode 108. The first frequency is a generally “low frequency,” e.g., 100 kHz to 27 MHz. The first frequency can be less than 13 MHz, e.g., the first frequency can be 2 MHz.

RF power at a second frequency is also applied to the lower electrode 114. The second frequency is a generally “low frequency,” e.g., 100 kHz to 27 MHz. In some implementations, the first and second frequency can be the same frequency. In some implementations, the second frequency is higher than the first frequency. For example, the second frequency can be greater than 2 MHz, e.g., the second frequency can be about 13 MHz.

Application of the RF power to the upper electrode 108 will ignite plasma in the chamber 100. The mere presence of the plasma will generate some hydrocarbon ions (as well as ions of the inert gas), which can be deposited on the workpiece to grow the diamond-like carbon film.

In addition, the upper electrode 108 is bombarded by the sheath accelerated ions, causing the upper electrode 108 to emit secondary electrons. The secondary electrons are accelerated by the plasma sheath voltage to an energy on the order of hundreds to thousands of electron volts, thus providing the secondary electron beam from the upper electrode 108 that propagates toward the workpiece 111.

Without being limited to any particular theory, a portion of the secondary electron beam can ionize the hydrocarbon feedstock gas in the chamber 100, thus increasing the hydrocarbon ion density in the plasma. The hydrocarbon ions in the plasma can be accelerated toward the workpiece 111 by the bias power applied to the lower electrode 114. This can cause the hydrocarbon ions to be implanted in the diamond-like carbon film as it is being deposited, thus increasing the film density. In effect, the film can be grown in an ion-implantation manner.

Still without being limited to any particular theory, this processing technique can provide a higher ratio of high energy electrons to low energy electrons in comparison to conventional plasmas in which electrodes are heated by RF fields to disassociate and ionize background gases. Thus, this processing technique can increase the ion-to-neutral ratio in comparison to conventional plasmas.

This deposition process can be carried out with the workpiece at a relatively low temperature, e.g., 10-60° C. Consequently, the pedestal 110 supporting the workpiece 111 does not need to be heated. In some implementations, the pedestal 110 is cooled. A coolant gas, e.g., helium, can flow between the pedestal 110 and the backside of the workpiece 111 to improve heat transfer between the workpiece 111 and the pedestal 110. The workpiece 111 can be electrostatically clamped to the pedestal 110, e.g., by application of a chucking voltage to the electrode 304.

The deposition process can proceed, e.g., for 5-100 seconds. Selection of appropriate power levels and other processing conditions according to the guidelines above can provide deposition rate greater than 6 μm/hour. In addition, the resulting film of diamond-like carbon can have a density greater than 2 g/cm³.

For deposition, the upper electrode 108 can be formed of carbon. In addition to generating secondary electron beams, the sputtered carbon atoms can also redeposit on the workpiece, thus contributing to the hydrocarbon plasma DLC deposition. As sputtered carbon atoms do not have hydrogen atoms bonded to them, this sputtering deposition component tends to increase film density. Therefore, a carbon electrode can be used to increase film density and modulate film stress.

A process for “curing” of a diamond-like carbon film begins with the film of diamond-like carbon already formed on the substrate. The film of diamond-like carbon could be formed according to the process laid out above, or by a different process. In addition, the diamond-like carbon film could be cured in the same chamber that was used for deposition of the diamond-like carbon film, or in a different chamber. If curing occurs in the same chamber, then the workpiece need not be removed from the chamber between the deposition and curing steps.

In the “curing” process, an inert gas, e.g., argon or helium, is supplied to the chamber 100 (the feedstock gas is not supplied in this process). The gas supply can establish a pressure of 10 to 200 mTorr.

RF power is supplied to the upper electrode 108 and the lower electrode 114 as described above. In some implementations, the frequencies used for curing can be the same as the frequencies used for deposition. In some implementations, the frequencies used for curing are different than the frequencies used for deposition. The frequencies can be in the range of 100 KHz to 80 MHz.

The workpiece can be subjected to these conditions for, e.g., 2 seconds to 5 minutes.

Without being limited to any particular theory, a portion of the secondary electron beam can pass through the plasma of inert gas and directly impinge the layer on the workpiece 111. These electrons can drive off hydrogen from the layer, and can decrease dangling bonds and increase cross-linking. As a result, stress in the deposited layer can be reduced.

An alternative process for “curing” of a diamond-like carbon film is performed as the process discussed above, e.g., with a plasma of inert gas, but the power and frequencies applied to the upper electrode 108 and lower electrode 114 are such that a secondary electron beam is not generated. Thus, the workpiece is simply exposed to the plasma of inert gas.

In some implementations, a film of diamond-like carbon can be grown by repeatedly alternating between the deposition and “curing” processes. The same chamber can be used for both processes; the workpiece does not need to be removed between processes. For example, after deposition of an initial layer of diamond-like carbon, the feedstock gas can be evacuated from the chamber 100 and the chamber 100 refilled with the inert gas. This inert gas is then used to perform the “curing” process. After the curing process, the feedstock gas is reintroduced into the chamber 100, and the deposition process is repeated to form another layer of diamond-like carbon over the initial layer. The second layer of diamond-like carbon can then be subjected to the “curing” process. Referring to FIG. 4, the deposition step (650) and “curing” step (660) can be iterated (670), thus depositing and treating consecutive layers onto the workpiece, until a film of a desired thickness has been formed.

In some implementations, multiple frequencies of bias power can be applied simultaneously to the same electrode, e.g., to the lower electrode 114. Use of multiple frequencies of bias power can enhance the film density and reduce the film stress. The lower frequency RF power can boost ion bombarding energy, and applying higher frequencies RF power simultaneously can increase ion flux. Each of the frequencies can be in the range of 100 KHz to 80 MHz. The lower frequency can be at 2 MHz or below, whereas the higher frequency can be above 2 MHz. For example, a combination of 2 MHz and 13 MHz, or 400 KHz and 13 MHz, etc., can be applied to the lower electrode 114. In addition, three or more frequencies could be applied.

While the foregoing is directed to various implementations, other implementations may be devised that are within the scope of the claims that follow.

What is claimed is:

1. An electron beam plasma reactor comprising:
a plasma chamber having a side wall;
an upper electrode;
a workpiece support to hold a workpiece facing the upper electrode, wherein the workpiece on the support has a clear view of the upper electrode;
a first RF power source coupled to said upper electrode;
a gas supply;
a vacuum pump coupled to the chamber to evacuate the chamber;
a controller configured to operate the first RF power source to apply an RF power to upper electrode, and to operate the gas distributor and vacuum pump, so as to create a plasma in an upper portion of the chamber that generates an electron beam from the upper electrode toward the workpiece and a lower electron-temperature plasma in a lower portion of the chamber including the workpiece.

2. The reactor of claim 1, wherein the controller is configured to operate the first RF power source such that the at least a portion of the electron beam emitted from upper electrode produces the low electron-temperature plasma.

3. The reactor of claim 1, comprising a bias voltage generator coupled to the workpiece support.

4. The reactor of claim 1, wherein said top electrode comprises one of silicon, carbon, silicon carbide, silicon oxide, aluminum oxide, yttrium oxide, or zirconium oxide.

5. The reactor of claim 1, comprising a first electromagnet or permanent magnet adjacent and surrounding the upper portion of the chamber and a second electromagnet or permanent magnet adjacent and surrounding the lower portion of the chamber.

6. The reactor of claim 1, comprising a window in the side wall in the upper portion of the chamber, a coil antenna around the window, and an RF generator coupled to the coil antenna.

7. The reactor of claim 1, wherein the gas supply is configured to supply an inert gas to the chamber.

8. The reactor of claim 1, wherein the gas supply is configured to supply a process gas to the chamber.

9. The reactor of claim 1, wherein a distance between the upper electrode and the workpiece support is sufficiently large to establish a temperature gradient in the plasma vertically through the chamber.

10. The reactor of claim 1, wherein the lower electron-temperature plasma in the lower portion of the chamber has an electron-temperature at or lower than an electron-temperature to deposit or anneal a layer of diamond-like carbon.

11. A method of processing a workpiece in a plasma reactor, comprising:
supporting a workpiece in a chamber of the plasma reactor such that the workpiece faces an upper electrode and has a clear view of an upper electrode;
introducing a gas into the chamber; and
applying a first RF power to the upper electrode so as to create a plasma in an upper portion of the chamber such that ions of the plasma impact the upper electrode and generate an electron beam of secondary electrons from the upper electrode toward the workpiece, wherein a first portion of the electron beam impinges the workpiece.

12. The method of claim 11, wherein a second portion of the electron beam generate a lower electron-temperature plasma in a lower portion of the chamber including the workpiece.

13. The method of claim 11, wherein introducing the gas establishes a pressure of 10 to 200 mTorr in the chamber.

14. The method of claim 11, wherein the gas is an inert gas.

15. The method of claim 11, wherein the gas is a process gas.

16. The method of claim 11, comprising applying a bias voltage to the workpiece support.

17. The method of claim 11, wherein said top electrode comprises one of silicon, carbon, silicon carbide, silicon oxide, aluminum oxide, yttrium oxide, or zirconium oxide.

18. The method of claim 11, comprising applying a first magnetic field from a first electromagnet or permanent magnet adjacent to the upper portion of the chamber and applying a second magnetic field from a second electromagnet or permanent magnet to the lower portion of the chamber.
